(19) United States
(12) Patent Application Publication
(10) Pub. No.: US 2008/0238311 A1
(43) Pub. Date: Oct. 2, 2008

(54) ORGANIC LIGHT EMITTING DISPLAY DEVICE AND METHOD OF FABRICATING THE SAME

(76) Inventors: Un-Cheol SUNG, Anyang-si (KR); Jin-Koo Chung, Suwon-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/040,759

(22) Filed: Feb. 29, 2008

(30) Foreign Application Priority Data
Mar. 30, 2007 (KR) 10-2007-0031245

(51) Int. Cl. H01H 1/62; H01H 9/02

(52) U.S. Cl. 313/512; 445/25

(57) ABSTRACT

An organic light emitting display device and a method of fabricating the same are disclosed. One embodiment includes an organic light emitting display device including an anode, an organic light emitting layer, and a cathode on a substrate, an encapsulation member protecting the organic light emitting display device, a first sealant bonding the substrate and the encapsulation member together, and a second sealant formed of a frit glass to adhere to a periphery of the first sealant.

### CROSS-REFERENCE TO RELATED APPLICATION

This application claims priority under 35 U.S.C. §119 to Korean Patent Application No. 10-2007-0031245, filed on Mar. 30, 2007 in the Korean Intellectual Property Office (KIPO), the contents of which is incorporated herein by reference in its entirety.

### BACKGROUND

1. Field of Disclosure

The present disclosure relates to an organic light emitting display (“OLED”) device and a method of fabricating the same.

2. Description of the Related Technology

Generally, a video display corresponds to a core technology for implementing information as images in an information communication age that is evolving toward high performance, slimness, lightness, and portability. In this regard, OLED devices are considered by some persons as the primary flat panel display capable of reduced weight and volume to overcome the disadvantages of a cathode ray tube (CRT).

An OLED device is a display device that emits light by injecting electrons and holes from an electron injecting electrode (cathode) and a hole injecting electrode (anode) into a light emitting layer; the electrons and holes are combined together as they fall from an excited state to a ground state.

When compared with other flat panel technologies, OLED devices offer advantages such as low driving voltage, low power consumption, light weight, and natural color display. However, they also have a comparatively shorter lifespan. One of the factors affecting the lifespan of the OLED device is oxidation attributed to permeation of oxygen and/or moisture into the device.

In a known encapsulation method, desiccant is attached to an encapsulation member and bonded to a substrate provided with the OLED device using a sealant. Alternatively, the substrate provided with the OLED device and the encapsulation member are bonded together by epoxy modeling compound.

However, due to properties of the sealant, the encapsulation method is generally incapable of preventing permeation of moisture or oxygen into the display device thereby, limiting the lifespan of the OLED device.

### SUMMARY

The present disclosure provides an OLED device and a method of fabricating the same that substantially solves one or more problems due to the limitations and disadvantages of the related art.

An object of the present disclosure is to provide the OLED device and a method of fabricating the same by which durability and lifespan are enhanced by forming a second sealant using a frit glass on a periphery of a first sealant in the process of OLED encapsulation.

In accordance with one embodiment, an OLED includes an OLED element including an anode, an organic light emitting layer, a cathode on a substrate, an encapsulation member protecting the OLED element, a first sealant bonding the substrate and the encapsulation member together, and a second sealant formed of a frit glass to adhere to a periphery of the first sealant.

In one embodiment, the OLED device further includes a desiccant provided between the OLED element and the encapsulation member.

In one embodiment, a space between the OLED element and the encapsulation member is filled with inert gas.

In one embodiment, the OLED device further includes a passivation layer between the OLED element and the encapsulation member.

In one embodiment, the first sealant includes one of an epoxy resin or an acryl resin.

In one embodiment, the first sealant is formed of the frit glass.

In one embodiment, the second sealant includes the frit glass formed of a mixture of a ceramic substance and an organic substance.

In another aspect of the disclosure, a method of fabricating an OLED device includes preparing a substrate including an anode, an organic light emitting layer, and a cathode; preparing an encapsulation member; providing a first sealant to one of the substrate or the encapsulation member; bonding the substrate and the encapsulation member together; providing a second sealant to a periphery of the first sealant using a frit glass; and plasticizing the frit glass.

In one embodiment, the second sealant is provided in a manner of dipping the periphery of the first sealant in the frit glass in a viscous liquid state.

In one embodiment, the second sealant is prepared in a manner of coating the second sealant in a viscous liquid state on the periphery of the first sealant using a syringe.

In one embodiment, the frit glass is plasticized using a laser or heat.

In one embodiment, preparing the substrate includes forming the OLED element; forming a driving thin film transistor and a switching thin film transistor on the substrate; forming a protecting layer to cover the driving and switching thin film transistors; forming a color filter on the protecting layer; forming a planarizing layer on the protecting layer and the color filter layer to include first, second, and third contact holes; forming a transparent conductive pattern including a connecting electrode and the anode on the planarizing layer; forming a barrier layer on the planarizing layer and the connecting electrode; forming the organic light emitting layer on the anode to be overlapped with the anode; and forming the cathode on the barrier layer and the organic light emitting layer.

### BRIEF DESCRIPTION OF THE DRAWINGS

The above and other features of the present disclosure will be described in reference to certain exemplary embodiments depicted in the attached drawings in which:

FIG. 1 is a plan view showing a substrate including OLED element according to one embodiment;

FIG. 2 is a cross-sectional view taken along line I-I′ in FIG. 1;

FIG. 3A and FIG. 3B are each cross-sectional views showing an encapsulation member according to an embodiment of the present disclosure;

FIG. 4 is a flowchart of a process for forming a frit glass according to one embodiment of the present disclosure;

FIG. 5A and FIG. 5B are cross-sectional views of the substrate and the encapsulation member bonded together according to one embodiment of the present disclosure;

FIG. 6 illustrates a method of coating a frit glass on a cross-section view taken along line II-II′ in FIG. 5A or FIG. 5B by dipping;

FIG. 7 illustrates a method of coating a frit glass on a cross-section view taken along line II-II′ in FIG. 5A or FIG. 5B using a syringe; and

FIG. 8 illustrates a second sealant forming method according to one embodiment of the present disclosure.

### DETAILED DESCRIPTION

Reference will now be made in detail to embodiments of the present disclosure, depictions of which are illustrated in the accompanying drawings, wherein like reference numbers refer to generally like elements throughout. The embodiments are described below in order to explain the present disclosure by referring to the figures.

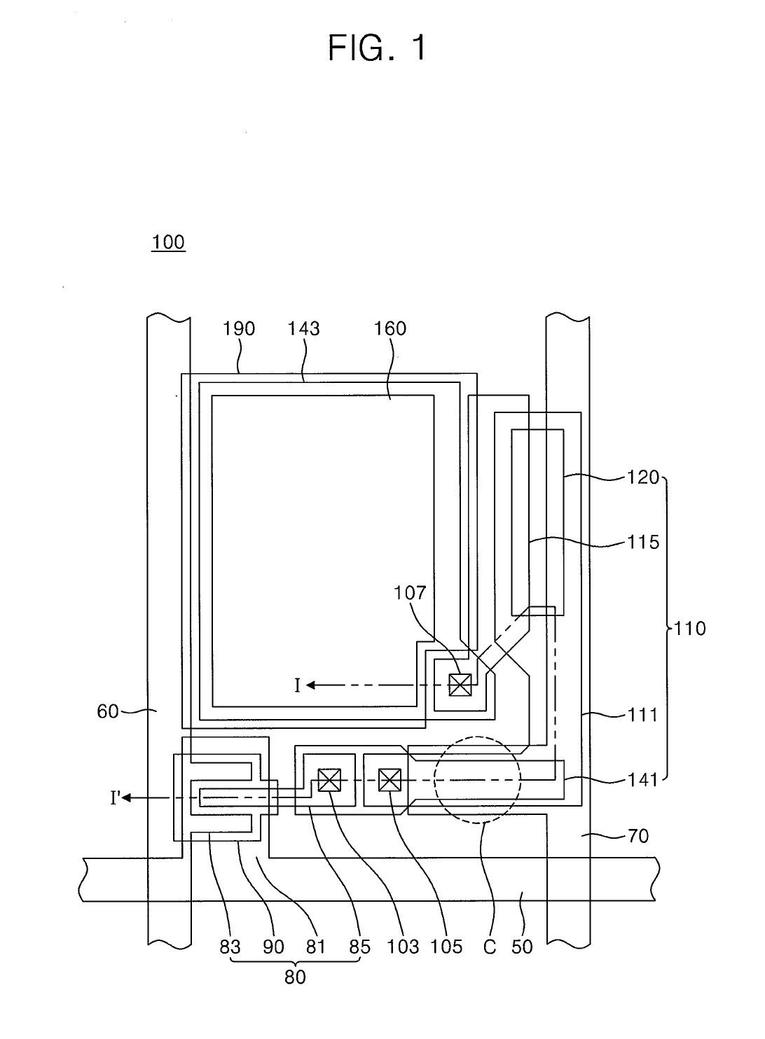

Hereinafter, embodiments of the present disclosure will be described in detail with reference to FIGS. 1 to 8. In the drawings, the thickness of layers and regions may be exaggerated for purpose of illustrative clarity.

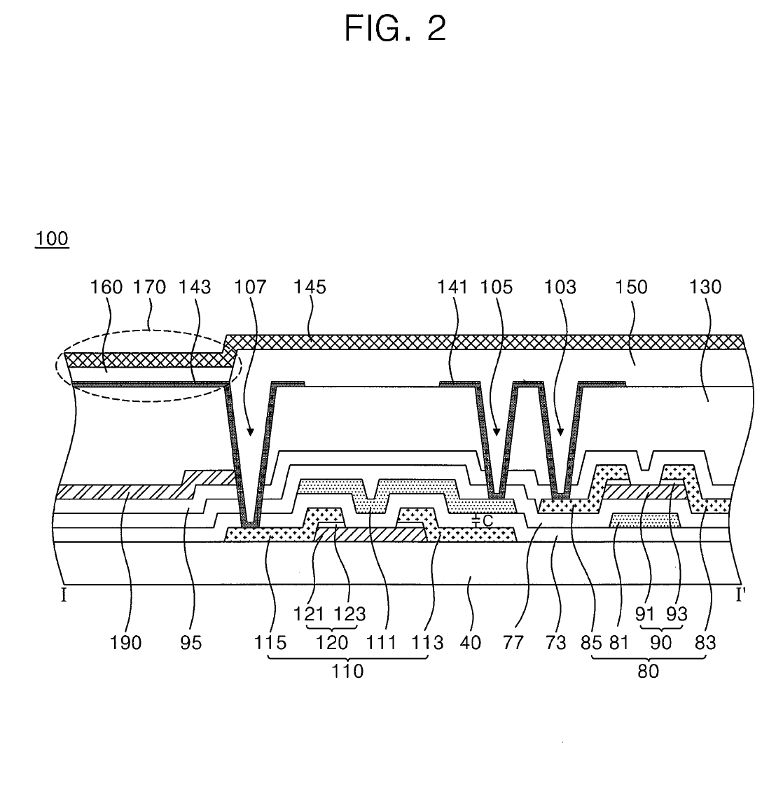

FIG. 1 is a plan view showing a substrate including OLED element according to an embodiment of the present disclosure, and FIG. 2 is a cross-sectional view taken along line I-I′ in FIG. 1.

Referring to FIG. 1 and. FIG. 2, a substrate 100 including an OLED element 170 according to an exemplary embodiment of the present disclosure includes a gate line 50, a data line 60, a power line 70, a switching thin film transistor (“TFT”) 80, a driving TFT 110, an anode 143, an organic light emitting layer 160, and a cathode 145.

The gate line 50 supplies a gate signal to the switching TFT 80. The data line supplies a data signal to the switching TFT 80, and the power line 70 supplies a power signal to the driving TFT 110.

When a scan pulse is supplied to the gate line 50, the switching TFT 80 is turned on to supply the data signal applied to the data line 60 to a storage capacitor C and a second gate electrode 111 of the driving TFT 110. The switching TFT 80 includes a first gate electrode 81 connected to the gate line 50, a first source electrode 83 connected to the data line 60, a first drain electrode 85 opposing the first source electrode 83 connected to the second gate electrode 111 of the driving TFT 110 and the storage capacitor C, and a first semiconductor pattern 90 forming a channel portion between the first source electrode 83 and the first drain electrode 85.

The first semiconductor pattern 90 includes a first active layer 91 overlapping the first gate electrode 81 with a second gate insulating layer 77 disposed therebetween, and a first ohmic contact layer 93 formed on the first active layer 91, other than the channel portion, for ohmic contact with the first source electrode 83 and the first drain electrode 85. Since the switching TFT 80 generally requires good on-off characteristics, the first active layer 91 may be formed of amorphous silicon which is advantageous to the on-off operations.

The driving TFT 110 adjusts luminescent intensity of the OLED element 170 by controlling a current supplied to the OLED device 170 from the power line 70 in response to the data signal supplied to the second gate electrode 111. The driving TFT 110 includes a second gate electrode 111 connected to the first drain electrode 85 of the switching TFT 80 via a connecting electrode 141, a second source electrode 113 connected to the power line 70, a second drain electrode 115 connected to the anode 143 of the OLED element 170 to oppose the second electrode 113, and a second semiconductor pattern 120 forming a channel portion between the second source electrode 113 and the second drain electrode 115. The connecting electrode 141 connects the first drain electrode 85 of the driving TFT 80 exposed via a first contact hole 103 to the second gate electrode 111 of the switching TFT 80 exposed via a second contact hole 105. The first contact hole 103 penetrates a protecting layer 95 and a planarization layer 130 to expose the first drain electrode 85. The second contact hole 105 penetrates the second gate insulating layer 77, the protecting layer 95, and the planarization layer 130 to expose the second gate electrode 111.

The second semiconductor pattern 120 includes a second active layer 121 overlapping the second gate electrode 111 with a first gate insulating layer 73 disposed therebetween, and a second ohmic contact layer 123 formed on the second active layer 121, other than the channel portion, for ohmic contact with the second source electrode 113 and the second drain electrode 115. The second active layer 121 may be formed of polysilicon to facilitate continuous current flow in the driving TFT 110 during the light emission period of the OLED element 170.

The power line 70 overlaps the second gate electrode 111 of the driving TFT 110 with the first gate insulating layer 73 disposed therebetween to form the storage capacitor C. The driving TFT 110 receives a charging voltage from the storage capacitor C and supplies a predetermined current to the OLED element 170 until a data signal from the next frame is received. In this manner, the OLED element 170 maintains the light emission, even though the switching TFT 80 is turned off.

The cathode 145 faces the anode 143 with the organic light emitting layer 160, formed in the unit of a sub-pixel unit, disposed therebetween. The anode 143 is independently formed on the planarizing layer 130 in each sub-pixel area to overlap a color filter 190. The anode 143 is connected to the second drain electrode 115 of the driving TFT 110 exposed via the third contact hole 107 penetrating the protecting and planarizing layers 95 and 130. The anode 143 may be formed of one of indium tin oxide (ITO), tin oxide (TO), indium zinc oxide (IZO), indium tin zinc oxide (ITZO), etc. The cathode 145 may be formed of one of Al, Mg, Ag, Ca, and the like to provide good reflectivity performance and electron supplying power.

The color filter 190 is formed on the protecting layer 95 to overlap the organic light emitting layer 160 generating white light. The color filter 190 displays red (“R”), green (“G”) and blue (“B”) using the white light generated from the organic light emitting layer 160. The R, G and B light generated in the color filter 190 is emitted to the outside the OLED device through an insulating substrate 40.

The OLED device 170 includes the anode 143 formed of a transparent conductive material and on the planarizing layer 130. An organic light emitting layer 160 having an emitting layer is formed on the anode 143, while the cathode 145 is stacked on the organic light emitting layer 160. The organic light emitting layer 160 includes a hole injecting layer, a hole transport layer, an emitting layer, an electron transport layer, and an electron injecting layer, which are stacked on the anode 143. In one embodiment, the emitting layer may include sequentially deposited R, G and B layers or two color layers having a complementary relationship. Also, the emitting layer may be implemented with a single layer emitting white light. The emitting layer included in the organic light emitting layer 160 emits light in the direction of the color filter 190 according to the current from the anode 143 to the cathode 145.

The barrier layer 150 is formed on the anode 143. The barrier layer 150 is made of a photoresist material and functions as an insulating layer. The barrier layer 150 blocks light generated from the organic light emitting layer 160.

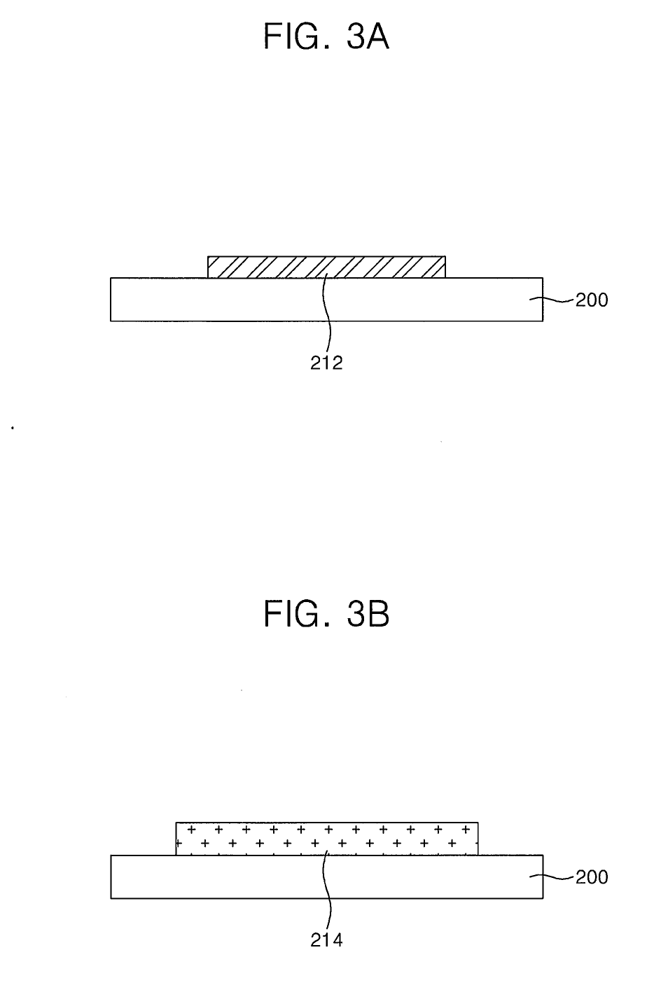

FIG. 3A and FIG. 3B are each cross-sectional views showing an encapsulation member according to an exemplary embodiment of the present disclosure.

Referring to FIG. 3A, a desiccant 212 is formed on an encapsulation member 200 to protect the OLED element 170. The encapsulation member 200 is formed one of a metal based material or a transparent material such as glass and the like. The desiccant 212 contains an element for absorbing moisture and oxygen and is formed of a transparent material. The desiccant 212 may include one of a nano-particle desiccant with a silicon dioxide (SiO₂) base, a chemical reaction desiccant with a calcium oxide (CaO) dispersion base, a nano-particle desiccant with silicon dioxide (SiO₂) and calcium chloride (CaCl₂) bases, an organic-inorganic desiccant with an organic-inorganic complex desiccant base, and the like. The desiccant 212 improves the lifespan of the OLED device by absorbing moisture and oxygen permeating into the OLED device.

Referring to FIG. 3B, a passivation layer 214 is formed on the encapsulation member 200. The passivation layer 214 may be formed of inorganic substance such as silicon dioxide (SiO2), silicon nitride (SiNx), silicon oxynitride (SiON), aluminum oxide (Al₂O₃) and the like, or organic substance such as polyethylene terephthalate (PET), polyvinylidene fluoride (PVDF), polymethylmethaacrylate (PMMA), polyimide (PI), and the like. The passivation layer 214 protects the OLED device from an external pressure.

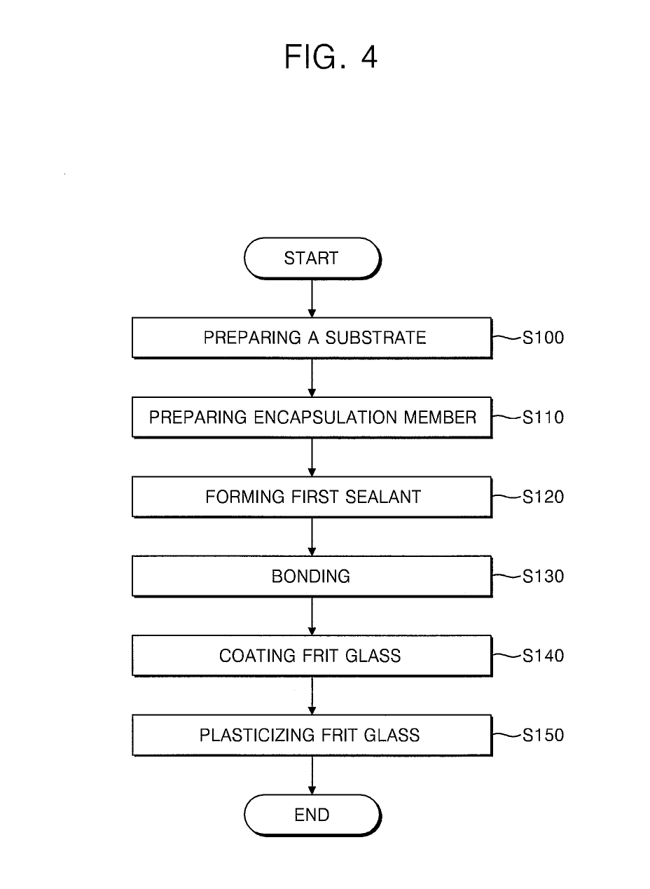

FIG. 4 is a flowchart of a process for forming a frit glass according to an exemplary embodiment of the present disclosure.

A process for forming a frit glass according to an exemplary embodiment of the present disclosure, the process includes a substrate preparing step S100, an encapsulation member preparing step S110, a first sealant forming step S120, a bonding step S130, a frit glass coating step S140, and a frit glass plasticizing step S150.

In the substrate preparing step S100, a substrate including an OLED element is prepared. The substrate including the OLED element preferably has the configuration of the substrate as shown in FIG. 1 and FIG. 2.

In the encapsulation member preparing step S110, an encapsulation member, as shown in FIG. 3A and FIG. 3B, is prepared to protect the OLED element.

In the first sealant forming step S120, in order to bond the substrate including the OLED element and the encapsulation member together, a first sealant is formed on a periphery of the substrate including the OLED element with about 0.1-2 mm width. The first sealant may be formed by a printing method using a screen mask or a method of directly coating on a corresponding portion using a first sealant dispenser. Preferably, the first sealant includes an epoxy resin or an acryl resin. In the aforesaid exemplary embodiment, the first sealant is formed on the substrate including the OLED device. Alternatively, the first sealant may be formed on an encapsulation substrate.

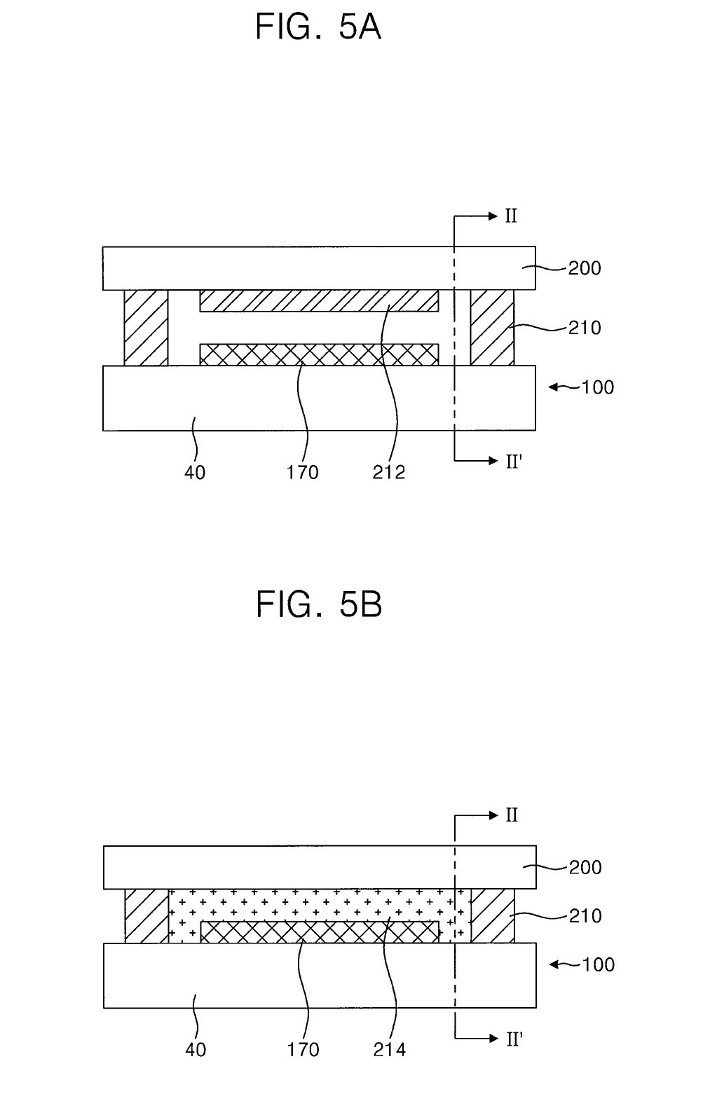

In the bonding step S130, the substrate including the OLED element and the encapsulation member are bonded together in a manner of being aligned and then pressurized. As shown in FIG. 5A and FIG. 5B described later, a substrate 100 provided with an OLED element 170 and an encapsulation member 200 are bonded together by a first sealant 210.

In the frit glass coating step S140, frit glass is coated on a periphery of the first sealant of the bonded substrate and encapsulation member. The frit glass coating step S140 may be carried out by dipping or by using a syringe. The frit glass is formed by mixing ceramic material such as silicon oxide (SiO₂), vanadium oxide (V₂0₃), and the like with organic material. Concentration of the frit glass is adjustable. If a rate of organic material is raised the frit glass has thin viscosity.

In the frit glass plasticizing step S150, the frit glass coated on the periphery of the first sealant of the substrate including the OLED element and the encapsulation member is plasticized using laser or the like to form a second sealant.

FIG. 5A and FIG. 5B are cross-sectional views for a substrate and an encapsulation member bonded together according to an exemplary embodiment of the present disclosure.

Referring to FIG. 5A, an encapsulation member 200 provided with a desiccant 212 and a substrate 100 including an OLED element 170 are bonded together using a first sealant 210. In doing so, inert gas is injected between the OLED element 170 and the encapsulation member 200. Preferably, the inert gas includes one of nitrogen (N₂), argon (Ar), and the like.

Referring to FIG. 5B, an encapsulation member 200 provided with a passivation layer 214 and a substrate 100 including an OLED element 170 are bonded together using a first sealant 210. The passivation layer 214 provided between the OLED element 170 and the encapsulation member 200 protects the OLED element 170 from an external shock or impact.

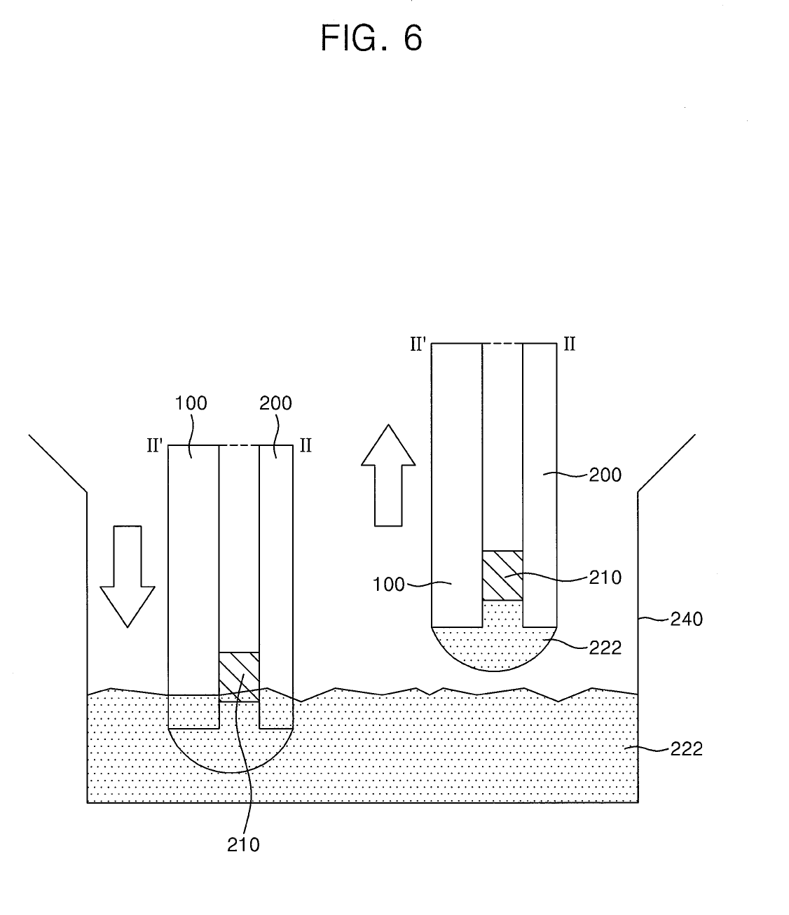

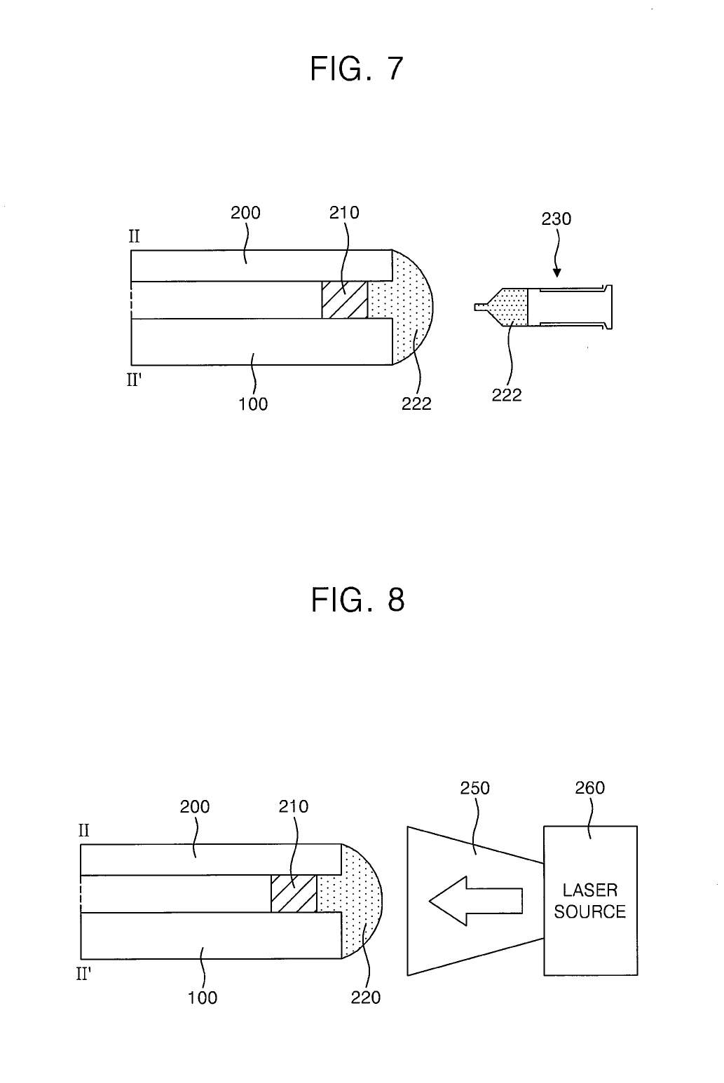

Meanwhile, the frit glass coating step S140 shown in FIG. 4 is explained in detail with reference to FIG. 6 and FIG. 7 as follows. FIG. 6 shows a method of coating frit glass to form a second moisture absorbent by a dipping method. FIG. 7 shows a method of coating frit glass to form a second moisture absorbent using a syringe, respectively.

FIG. 6 illustrates a method of coating a frit glass on a cross-section view taken along line II-II′ in FIG. 5A or FIG. 5B by a dipping method.

In a method of coating the frit glass 222 by dipping, a melted frit glass 222 is put into a container 240. In this case, the frit glass 222 preferably has viscosity suitable for allowing the frit glass 222 to adhere to a periphery of a first sealant 210, which bonds a substrate 100 including an OLED element and an encapsulation member 200 together, and encloses the first sealant 210 and the bonding part. In one embodiment, the viscosity of the frit glass 222 is below 30,000 cp.

Subsequently, the periphery of the first sealant 210, which bonds the substrate 100 including the OLED element and the encapsulation member 200 together, is dipped into the melted frit glass 222 within the container 240, whereby a prescribed quantity of the frit glass 222 adheres thereto.

The substrate 100 including the OLED element and the encapsulation member 200, which are bonded together by the first sealant 210 having the frit glass 222 adhere to its periphery, proceed to the frit glass plasticizing step S150.

FIG. 7 illustrates a method of coating a frit glass on a cross-section view taken along line II-II′ in FIG. 5A or FIG. 5B using a syringe.

In a method of coating a frit glass 222 using a syringe 130, a melted frit glass 222 is loaded in the syringe 230. In one embodiment, the frit glass 222 has viscosity suitable for injecting the frit glass 222 to a periphery of a first sealant 210 which bonds a substrate 100 including an OLED element and an encapsulation member 200 together.

Subsequently, the frit glass 222 loaded in the syringe 230 is injected to the periphery of the first sealant 210 that bonds the substrate 100 and the encapsulation member 200 together to enclose both of the first sealant 210 and the bonding part. The substrate 100 including the OLED element and the encapsulation member 200, which are bonded together by the first sealant 210 having the frit glass 222 adhere to its periphery, then enter the frit glass plasticizing step S150.

FIG. 8 illustrates a second sealant forming method according to an exemplary embodiment of the present disclosure.

In a second sealant forming method according to an embodiment of the present disclosure, a frit glass coated on a periphery of a first sealant 210, which bonds a substrate 100 including an OLED element and an encapsulation member 200 together, is plasticized. The frit glass coated on the periphery of the first sealant 210 by the dipping or the syringe method is plasticized so that an energy source, e.g., a laser 250 of a laser source 260, is irradiated on the frit glass to harden.

The second sealant 220 generated from plasticizing the frit glass has strong adhesiveness, high mechanical strength, and chemical durability suitable for use as an adhesive agent. If the second sealant 220 is formed of the frit glass, a separate desiccant is unnecessary due to the excellent water-vapor transmission rate of the frit glass. The second sealant 220 may provide a low water-vapor transmission rate for the first sealant 210. Moreover, the second sealant 220 is consistant in a drop test due to its superior adhesive power and durability.

Additionally, the frit glass is usable in forming the first sealant 210, which enhances durability and lifetime of the OLED device.

Accordingly, the present disclosure provides the following effects or advantages.

The present disclosure forms a second sealant of frit glass on a periphery of a first sealant in the course of encapsulation, thereby enhancing durability and the lifespan of an OLED device.

Additionally, frit glass has a good water-vapor transmission rate to permit omission of a separate desiccant and even provides a low water-vapor transmission rate of a first sealant. Moreover, the frit glass is consistant in a drop test due to its superior adhesive power and durability.

Although the present disclosure has been described with reference to certain exemplary embodiments thereof, it will be understood by those skilled in the art that a variety of modifications and variations may be made to the present disclosure without departing from the spirit or scope of the present teachings.

What is claimed is:

1. An organic light emitting display device comprising:
an organic light emitting display element including an anode, an organic light emitting layer, and a cathode on a substrate;
an encapsulation member protecting the organic light emitting display element;
a first sealant bonding the substrate and the encapsulation member together; and
a second sealant formed of a frit glass to adhere to a periphery of the first sealant.

2. The organic light emitting display device of claim 1, further comprising a desiccant provided between the organic light emitting display element and the encapsulation member.

3. The organic light emitting display device of claim 2, wherein a space between the organic light emitting display element and the encapsulation member is filled with inert gas.

4. The organic light emitting display device of claim 1, further comprising a passivation layer between the organic light emitting display element and the encapsulation member.

5. The organic light emitting display device of claim 1, wherein the first sealant comprises either an epoxy resin or an acryl resin.

6. The organic light emitting display device of claim 1, wherein the first sealant is formed of the frit glass.

7. The organic light emitting display device of claim 1, wherein the second sealant comprises the frit glass formed of a mixture of a ceramic material and an organic material.

8. A method of fabricating an organic light emitting display device, comprising:
preparing a substrate including an anode, an organic light emitting layer, and a cathode;
preparing an encapsulation member;
providing a first sealant to one of the substrate or the encapsulation member;
bonding the substrate and the encapsulation member together;
providing a second sealant to a periphery of the first sealant using a frit glass; and
plasticizing the frit glass.

9. The method of claim 8, wherein the second sealant is provided in a manner of dipping the periphery of the first sealant in the frit glass in a viscous liquid state.

10. The method of claim 8, wherein the second sealant is prepared in a manner of coating the second sealant in a viscous liquid state on the periphery of the first sealant using a syringe.

11. The method of claim 8, wherein the frit glass is plasticized using a laser or heat.

12. The method of claim 8, wherein preparing the substrate comprises:
forming the organic light emitting display element;
forming a driving thin film transistor and a switching thin film transistor on the substrate;
forming a passiviation layer to cover the driving and switching thin film transistors;
forming a color filter on the protecting layer;
forming a planarizing layer on the protecting layer and the color filter layer to include first, second, and third contact holes;
forming a transparent conductive pattern including a connecting electrode and the anode on the planarizing layer;
forming a barrier layer on the planarizing layer and the connecting electrode;
forming the organic light emitting layer on the anode to be overlapped with the anode; and
forming the cathode on the barrier layer and the organic light emitting layer.
